(19) United States
(12) Patent Application Publication
(10) Pub. No.: US 2025/0385228 A1
(43) Pub. Date: Dec. 18, 2025

(54) Power Electronics Assembly Comprising Power Modules That Can Be Fitted with Components

(71) Applicant: Siemens Aktiengesellschaft, München (DE)

(72) Inventors: Jörg Strogies, Berlin (DE); Matthias Heimann, Potsdam (DE); Bernd Müller, Falkenberg (DE); Klaus Wilke, Berlin (DE); Thomas Bigl, Herzogenaurach (DE); Alexander Hensler, Gerhardshofen (DE); Christian Nachtigall-Schellenberg, Potsdam (DE); Philipp Oschmann, Erlangen (DE); Stefan Pfefferlein, Heroldsberg (DE)

(73) Assignee: Siemens Aktiengesellschaft, München (DE)

(21) Appl. No.: 18/879,688

(22) PCT Filed: May 8, 2023
(86) PCT No.: PCT/EP2023/062138

§ 371 Date: Dec. 27, 2024

(30) Foreign Application Priority Data
Jun. 30, 2022 (EP) 22182129.1

(51) Int. Cl. H01L 25/11; H01L 23/00; H01L 23/31; H01L 23/373; H01L 23/498; H01L 23/538; H02M 7/00

(52) U.S. Cl. CPC H01L 25/112; H01L 23/3128; H01L 23/3735; H01L 23/49816; H01L 23/49844; H01L 23/5385; H01L 23/5386; H01L 24/08; H01L 25/115; H02M 7/003; H01L 2224/08238; H01L 2924/13055; H01L 2924/13091

(57) ABSTRACT

Various embodiments of the teachings herein include a power electronics assembly having a substrate with two loadable power modules. The two modules each comprise: a power substrate with a first metallization; a switchable die with power interfaces; an interposer; and two contact elements, each of which provides an electrical contact for one of the power interfaces at the interposer. The die is joined to the metallization of the power substrate and to the interposer. A gap is defined between the first substrate, the interposer, and the die, and closed off by an insulation material so the die is surrounded by the insulation material, the power substrate, and the interposer. At least one of the contact elements projects through the interposer and/or is part of the interposer.

### CROSS-REFERENCE TO RELATED APPLICATIONS

This application is a U.S. National Stage Application of International Application No. PCT/EP2023/062138 filed May 8, 2023, which designates the United States of America, and claims priority to EP Application No. 22182129.1 filed Jun. 30, 2022, the contents of which are hereby incorporated by reference in their entirety.

### TECHNICAL FIELD

The present disclosure relates to power electronics. Various embodiments of the teachings herein include power electronics assemblies with loadable power modules, converters, and electric vehicles.

### BACKGROUND

Some power electronics assemblies are deployed in industrial converters or in traction converters.

### SUMMARY

The teachings of the present disclosure include low-inductance assemblies with power modules that can be loaded in a conventional production line. For example, some embodiments include a power electronics assembly (200) having an assembly substrate (220) to which at least two loadable power modules (100) are electrically contacted, wherein the loadable power modules (100) each comprise: a power substrate (10) with at least a first metallization (14), at least one switchable die (40) with power interfaces (42,44), an interposer (50), and at least a first and a second contact element (62,64), each of which provides an electrical contacting for one of the power interfaces (42,44) of the die (40) at the interposer (50), wherein the die (40) is joined to the metallization (14) of the power substrate (10) and to the interposer (50) and is arranged between the power substrate (10) and the interposer (50), wherein a gap (22) that is formed by the first substrate (10), the interposer (50) and the die (40) is closed off by an insulation material (20), so that the die (30) is surrounded by the insulation material (20), the power substrate (10) and the interposer (50), wherein the interposer (50) is embodied in such a way that one or more of the contact elements (62,64) project through the interposer (50) and/or the interposer (50) provides one or more of the contact elements (62,64).

In some embodiments, the power modules (100) are arranged in such a way that the interposers (50) thereof are oriented toward the assembly substrate (220).

In some embodiments, the power modules (100) are arranged between the assembly substrate (220) and a heat sink (210).

In some embodiments, the interposer (50) is designed as a multilayer circuit support.

In some embodiments, the interposer (50) has an opening for one of the contact elements (62,64), this being electrically contacted to the first metallization (14).

In some embodiments, the interposer (50) is designed in such a way that power interfaces (42,44) and control interfaces (46) of all dies (40) are provided on a shared side of the interposer (5), on the opposite side to the power substrate (10).

In some embodiments, at least one of the contact elements (62,64) is designed for contacting by means of a compression method, in particular a press-fit method.

In some embodiments, at least one of the contact elements (62,64) is designed for contacting by means of a joining method.

In some embodiments, at least one of the contact elements (62,64) is designed for contacting by means of a spring force.

In some embodiments, the interposer (50) has a first metallic inlay (55), which is electrically contacted to a first power interface (42) of the die (40) and to a first contact element (62).

In some embodiments, the interposer (50) has a second metallic inlay (55), which is electrically contacted to a second power interface (44) of the die (40) and to a second contact element (64).

In some embodiments, the interposer (50) is embodied in such a way that a leakage distance (x2) in the gap (22) between a recontacting (18) of the electrical contacting for the first power interface (42) and the second power interface (44) of the die (40) is smaller than a clearance (x1) between the first contact element and the second contact element (44) projecting from the interposer (50).

In some embodiments, the interposer (50) has a control interface (66) which electrically contacts a control interface (46) of the die, wherein the control interface (66) of the interposer (50) is preferably arranged between the first and the second contact element (62,64).

As another example, some embodiments include a converter comprising at least one power electronics assembly (200) as described herein, which is designed to convert DC voltage into AC voltage and/or vice versa.

As another example, some embodiments include an electric vehicle having a converter as described herein as part of an electric drive.

### BRIEF DESCRIPTION OF THE DRAWINGS

The teachings of the present disclosure are described and explained in greater detail below with reference to the exemplary embodiments illustrated in the figures, in which:

FIG. 1 schematically shows a power module incorporating teachings of the present disclosure in cross section;

FIG. 2 schematically shows a further power module incorporating teachings of the present disclosure in cross section with contact elements;

FIG. 3 schematically shows a further power module incorporating teachings of the present disclosure in cross section with further contact elements;

FIG. 4 schematically shows an example power module incorporating teachings of the present disclosure with a pin which projects through the interposer;

FIG. 5 schematically shows two pins which project through the interposer;

FIG. 6 schematically shows an illustration of clearance and leakage distances on a power module incorporating teachings of the present disclosure;

FIG. 7 schematically shows a power module incorporating teachings of the present disclosure with an interposer which has inlays;

FIG. 8 schematically shows a power module incorporating teachings of the present disclosure with an interposer which has inlays with a control interface;

FIG. 9 schematically shows a one-sided power electronics assembly incorporating teachings of the present disclosure; and

FIG. 10 schematically shows a power electronics assembly incorporating teachings of the present disclosure which is loaded on both sides.

### DETAILED DESCRIPTION

The teachings of the present disclosure include power electronics assemblies having an assembly substrate to which at least two loadable power modules are electrically contacted, said power modules each comprising a power substrate with a metallization, at least one switchable die with power interfaces, an interposer and at least a first and a second contact element. The contact elements each provide an electrical contacting on the interposer for one of the power interfaces of the die, being designed in this case for the electrical contacting of the power interfaces of the die to a power electronics assembly. In other words, the contact elements provide an electrical contacting for the power interfaces of the die, which is arranged inside the power module, outside the power module, so that the module can be loaded and deployed on an assembly. The die is a semiconductor component which can be designed as an IGBT or MOSFET, for example. As an unpackaged semiconductor, it is also referred to as a bare die or a naked chip. Such naked chips are normally only processed under clean-room conditions and are therefore rarely processed directly in conventional SMD production lines. The inventive module can advantageously be processed in conventional electronics production lines and at the same time allows similarly low-inductance attachment to that which would be possible with the die itself.

In this case, depending on the semiconductor type, the power interfaces of the die are normally designed as source and drain, or collector and emitter. In the case of diodes, the power interfaces are designed as anode and cathode. The die is also joined to the metallization of the power substrate and to the interposer and arranged between the power substrate and the interposer. A gap between the first substrate, the interposer and the die is closed off by an insulation material, so that the die is surrounded by the insulation material, the power substrate and the interposer. This has the advantage that the naked chip is encapsulated in such a way that it can be processed in a conventional SMD production line. In this case, the interposer is embodied in such a way that the contact elements project through the interposer and/or the interposer provides the contact elements.

In some embodiments, the contact elements allow a low-inductance electrical contact to be established from the power electronics assembly to the die. In other words, the first and second contact elements are embodied to provide an electrical contacting for power interfaces of the die at the interposer, and therefore the die can be electrically contacted from outside the power module. In this case, the contact elements can be embodied as part of the interposer and electrically contacted to electrical conductors in the interposer. Such contact elements are commercially available in PCB technology or can be produced as metallization of the interposer.

This allows simple one-sided contacting of the die via the interposer and can be automated. Accordingly, the loadable power module can then be loaded onto a power electronics assembly. In some embodiments, the power module has one or at most two switchable dies in this case.

The interposer can have a higher thermal expansion coefficient than the power substrate in this case. This means that the interposer can be made from materials which are more economical and can be processed more flexibly and easily than the power substrate. The electrical contacting and the handling of dies are also significantly simplified by virtue of the power module during the installation thereof, the flexibility of the bare die being retained in respect of electrical configuration (topologies, power scaling) and arrangement within the component.

In some embodiments, the power module, and therefore the contact elements and the die, are designed for a reverse voltage of at least 24 V in this case, in particular at least 50 V or 100 V, and a load current of at least 1 A, in particular at least 5 A or 10 A.

In some embodiments, the power substrate is a metal-ceramic substrate. Cited here in particular are the so-called direct bonded copper and active metal brazing substrates. Such substrates have a thermal expansion coefficient that is adapted to the die, thereby giving a very high degree of stability, in particular against alternating thermal stresses. At the same time, it is also possible to achieve good heat conduction from the die toward a thermal interface of the substrate, which is on the opposite side of the substrate to the die.

In some embodiments, the interposer is a multilayer circuit support. The arrangement of lines in the multilayer circuit support can be embodied in a far more flexible manner than would be possible using a ceramic substrate, for example.

In some embodiments, the interposer is embodied as a plastic PCB, in particular a fiber-reinforced plastic PCB, an FR4 PCB, a so-called high-Tg PCB (having a glass transition temperature Tg higher than 150° C.), made from polyimide and/or as a pre-molded leadframe. For high-temperature applications, high-temperature interposer materials such as PI, PEEK or LCP for example have proven satisfactory.

In some embodiments, the interposer has metallic inlays. In particular, such inlays can be made from copper, embodied as solid metal blocks, and result in both improved current-carrying capacity and improved thermal conductivity at the connection interface of the power interfaces of the die. In this case, the inlays may be electrically connected to at least one of the power interfaces of the die, and can be attached to the die by way of vias in multilayer PCBs. Depending on power requirements, it is therefore conceivable for one or more vias to electrically contact a metallic inlay in each case and then correspondingly also to provide or to electrically contact the contact elements on the outside of the interposer. In other words, the inlays serve as electrical conductors for the contact elements, in order to allow a connection between the power interfaces of the die and a power electronics assembly.

In some embodiments, the interposer has an opening for one of the contact elements, said contact element being electrically contacted to the metallization. Since the dies normally have power interfaces on both upper and lower sides, the power interface which is in contact with the metallization of the power substrate must be recontacted in order to allow a one-sided connection interface of the power module via the interposer. This recontacting can be effected for example by means of a contact element which projects through the interposer. For example, a pin can be provided here, which serves as a connection interface or as a contact element of the power module. This can be a press-fit pin, which also allows good mechanical attachment by virtue of connection to the stable power substrate, with low-inductance properties. In some embodiments, the contact elements are made of solid connection interfaces which are configured for the power that is applied. In some embodiments, the pin can also have an electrical intermediate contacting at the interposer and consequently need not be electrically contacted to the metallization of the power substrate and can be placed there in an electrically isolated or completely isolated manner.

In some embodiments, the interposer is designed in such a way that power interfaces and control interfaces of all dies are provided on a shared side of the interposer, on the opposite side to the power substrate. This allows ease of loading and particularly low-inductance attachment of the power module in this case.

In some embodiments, at least one of the contact elements is designed for contacting by means of a compression method, in particular a press-fit method. Such methods include planar compression methods as well as press-fit connections. Such contacting methods are very low-inductance, easy to control and easy to work with.

In some embodiments, at least one of the contact elements is designed for contacting to the electronic assembly by means of a joining method. Such methods include in particular solder pins, planar sintered and/or solder connection pads (similar to a land grid array) or solder balls (similar to a ball grid array). Such joining areas are particularly low-inductance and can also be joined easily by virtue of the flat or planar construction of the power module in particular.

In some embodiments, at least one of the contact elements is designed for contacting by means of a spring force. A low-inductance electrical connection can be achieved, said connection being detachable at the same time.

In some embodiments, the interposer has a first metallic inlay, which is electrically contacted to a first power interface of the die and a first contact element. In some embodiments, the interposer has a second metallic inlay, which is electrically contacted to a second power interface of the die and a second contact element. In this way, the power interfaces can be extended out of the power module via the metallic inlays with a high current carrying capacity, very good thermal conductivity and low inductance.

In some embodiments, the interposer is embodied in such a way that a leakage distance in the gap between a recontacting of the first power interface and the second power interface of the die is smaller than a clearance between the first contact element and the second contact element. This means that the contact elements extending out of the power module and provided by the interposer may have a significantly greater separation in the air (i.e. at the contact elements that are accessible externally to the power module) than would be allowed by the space conditions in the power module or in the immediate surroundings of the die. Such a distortion correction also has a positive effect on the power and the power density of the power module and eliminates the need for further insulation material outside the power module or allows the use of more economical insulation materials. The distortion correction of the leakage distance and clearance can be realized with or without inlays in this case.

In some embodiments, the interposer has a control interface which electrically contacts a control interface of the die. The control interface of the interposer in this case can be arranged between the first and the second contact element. This not only saves space but also does not alter the insulation requirements, since the control interface lies on a different potential than the power interfaces. Very compact construction is therefore possible.

By virtue of the inventive construction of the power modules, the assembly substrate can be embodied as a conventional (for example FR4) PCB, since heat dissipation is effected via the power substrates of the power modules, these being arranged on the opposite side to the assembly substrate, and a distortion correction of the power density is effected by means of the interposer.

In some embodiments, the power electronics assembly can be embodied in such a way that the interposers of the power modules are so arranged as to be oriented toward the assembly substrate. In other words, the interposer with the contact elements provides the electrical contacting for the assembly substrate.

In some embodiments, the power modules are arranged between the assembly substrate and a heat sink. This means that the interposer faces toward the assembly substrate and the power substrate of the power module can be connected directly to the heat sink via a thermal interface, for example. In this case, the heat sink can also serve to ensure a level connection in relation to the power substrates and module alignment.

In comparison with fully integrated solutions in the form of commercially available power modules comprising 4 or 6 switchable semiconductor modules (for example so-called sixpack modules), the present invention generally, and embodiments thereof specifically, may offer many advantages. The power module is a modular package with connection interfaces that can be standardized. Changes in respect of power semiconductors (different power semiconductor technologies such as for example IGBTs, MOSFETs, SiC, GaN) relate to the power module itself; the interposer could therefore remain the same in respect of connection interfaces. The powerboard (i.e. the assembly substrate) need not be changed. Adaptations of the power or the circuit topology can be realized, using an identical powerboard, by means of different power modules with correspondingly different power semiconductors or interconnections.

Layout changes on the powerboard (for example adjustment of the loading positions) can easily be implemented using standardized connection interface structures of the inventive power module. With regard to the configuration of a power electronics assembly, the power modules described herein have the advantage that it can be considered as a discrete component for the purpose of circuit design and can therefore be planned directly at the same time as the layout. Each individual power module is and remains fully testable electrically. In contrast with multiple semiconductors on a circuit support, which can only be tested as a complete structure, the yield can be increased significantly thereby.

For the thermal decoupling between power module and powerboard, the required area for potentially cost-intensive high-temperature interposer material is restricted to a minimum. Economical standard material can preferably be used for the powerboard.

Leveling of the individual power modules relative to each other and to the heat sink can be achieved in an elegant manner by means of press-fit technology or soldering-in using clamps, or with the aid of compensating connection elements. In the power electronics assembly, the individual thermal interfaces of the power modules can therefore be aligned with each other in a plane within a presettable tolerance.

Some embodiments include a converter having at least one power electronics assembly, and/or an electric vehicle having such a converter. The power electronics assembly can also be embodied as a DC/DC converter.

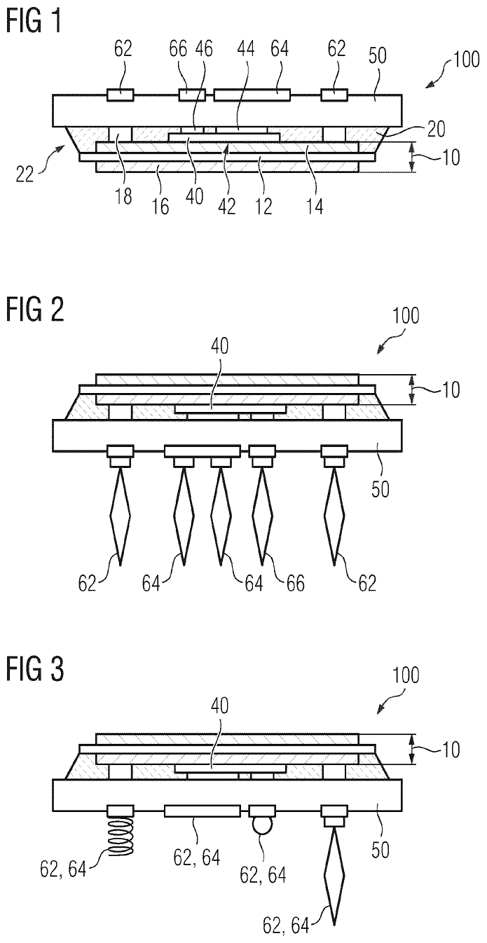

FIG. 1 shows a power module 100 incorporating teachings of the present disclosure and comprising a power substrate 10 which has a core 12, of ceramic in particular, a first metallization 14 and a second metallization 16. Placed, for example joined, onto the first metallization 14 is a die 40, here a switchable die 40. In this case, the die 40 is placed on and electrically contacted to the first metallization 14 via its first power interface 42, such that an electrical connection between the first power interface 42 of the die and an interposer 50 can be created via one or more instances of recontacting 18. In this case, the interposer 50 has contact elements 62,64 which make electrically available the first power interface of the die 42 by means of the first contact element 62, divided over two pads here, a second power interface of the die 44 by means of the second contact element 64, and a control interface 46 by means of a control interface 66 of the interposer 50. All connection interfaces of the die 40 are therefore made available at the interposer by means of contact elements 62,64 and the control interface 66.

The interposer 50 is illustrated only schematically in this case. Below the interposer 50 is an insulation material 20 which fills a gap 22 between the interposer 50, the power substrate 10 and the die 40. The instances of recontacting 18 are also surrounded by the insulation material 20. For example, an underfill material or a molding can be used here. In order to achieve maximum flexibility, it is advantageous to place only one IGBT with the associated freewheeling diode or only a limited number of parallel connected MOSFETs on one of the power substrates 10.

FIG. 2 shows a power module 100 as shown in FIG. 1, in which the contact elements 62,64 and the control interface 66 already have press-fit pins. In some embodiments, solder pins or rivets can be provided here. Such contact elements are easy to work with and can be deployed in standard processes.

FIG. 3 shows an alternative form of embodiment of a power module, a solder pad and solder ball now being provided as contact elements 62,64 at the interposer 50 in addition to the press-fit or solder pin. Such solder connections are known from ball grid arrays, for example, a power connection being provided by an appropriate number of balls or the size of the pad in the present case. Also conceivable are flat pads and/or spring connections. The connection elements can be combined in this case, though as a rule one type of connection element is used for all connections at the respective power module.

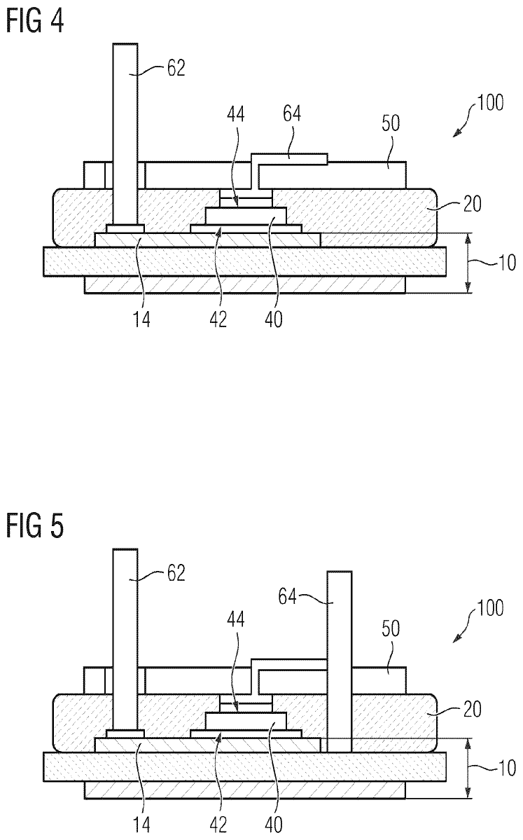

FIG. 4 shows a further form of embodiment of a power module 100, in which a first contact element 62 projects through the interposer 50. In this case, the contact pin or the contact element 62 is embodied in such a way that it is mounted on a metallization 14, which is connected to a first power interface 42 of the die 40, on a power substrate 10. In this way, no recontacting is necessary and a very low-inductance connection is created to the metallization 14 or the chip underside and the first power interface 42 arranged there. In this case likewise, the die 40 is surrounded by an underfill or a molding, which acts as insulation material 20. Such contact pins can be placed directly during the production of the metallization of the DCB or AMB substrates. A second contact element 64 can be embodied as described and is depicted here as an area. The second power interface 44 is connected to a second contact element 64 by means of an electrical conductor in the interposer 50. The second contact element 64 in this case can be embodied variously and according to the application, as per the forms of embodiment for the contact elements. In this case, the die 40 is joined by means of its power interfaces 42,44 to the substrate and the interposer 50. The die 40 can also have a control interface in this case (not shown here).

FIG. 5 shows a form of embodiment similar to FIG. 4, in which the first and the second contact elements 62,64 are each designed as a pin, the first contact element 62 being embodied as in FIG. 4 and being electrically contacted to the first power interface 42 of the die 40. The second contact element 64 is likewise designed as a pin, which is contacted via the interposer 50 to a second power interface 44 of the die 40. In this case, the second contact element 64 can be arranged as shown directly on the core of the substrate 10 but can also be placed on an electrically insulated island of the metallization 14. The die 40 can also have a control interface in this case (not shown here).

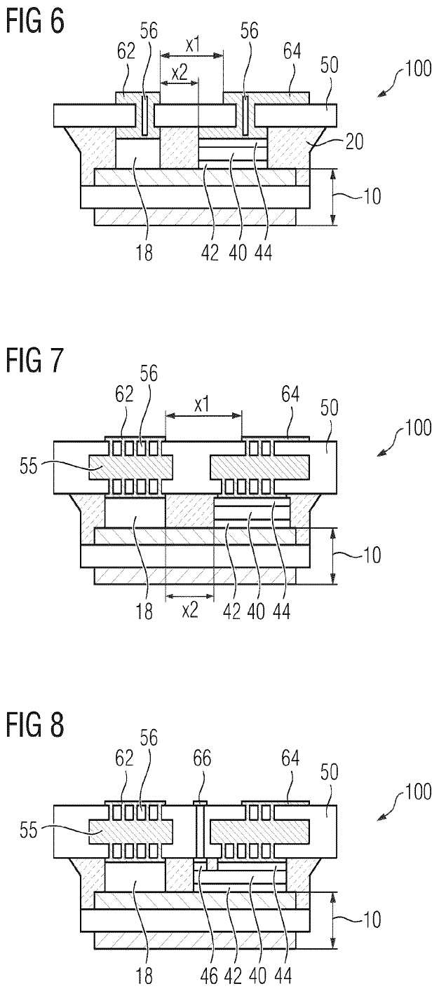

FIG. 6 shows a further form of embodiment of a power module 100, a clearance x1 and a leakage distance x2 being marked here. The clearance x1 is external to the power module 100, located between a first contact element 62 and a second contact element 64. The clearance x1 in this case is the separation which is provided as insulation, in the air or fluid in which the power module 100 is deployed, between the two power-conducting contact elements 62,64. This distance must be sufficiently large to satisfy insulation requirements in the respective power class. In this embodiment, the clearance x1 is greater than a leakage distance x2 which is found inside an insulation material 20. The spreading of the clearance x1 relative to the leakage distance x2 in this case is achieved by means of the interposer 50 and the contact elements 64,62 which are arranged thereby. In this case, the contact element 62 connects an instance of recontacting 18, which is connected via a metallization of the power substrate 10 to the first power interface 42 of the semiconductor 40, and a second contact element 64 is likewise connected via the interposer 50 to a second power interface 44 of the semiconductor or the die 40. The underside and upper side of the interposer are connected by vias 56 in this case, such that the clearance x1 is considerably greater than the leakage distance x2. The interposer is used in this way as an intermediate layer which can be configured in a flexible manner and spreads the power interfaces 62 and 64 accordingly. Control interfaces of the die 40 are not marked but can likewise be extended out via the interposer.

FIG. 7 shows a form of embodiment similar to that in FIG. 6, in which a multilayer interposer 50 is used and has metallic inlays 55 which allow improved and very low-inductance electrical contacting at the same time as spreading between clearance and leakage distance x1, x2. The inlays in this case preferably take the form of a thick copper layer in the center, this being contacted to the two outer layers by way of vias. The inlays offer very good thermal attachment as well as an excellent low-resistance vertical current path. The vias can be designed in particular as laser-drilled vias which are filled with copper. The resulting distortion correction of the load currents directly at the semiconductor or directly at the die 40 allows an optimized design and the use of standard multilayer PCBs.

FIG. 8 shows a further form of embodiment of a power module 100 with an interposer 50 which has inlays 55 and is similar to that in FIG. 6. This shows how a die 40 with a control interface 46 can also be contacted by means of the interposer 50. A control interface 66 of the interposer 50 is connected to the control interface 46 of the die 40 by way of a via through the multilayer interposer 50. Such an arrangement is also advantageous because the control interface 66 does not adversely affect the division of the clearance and leakage distances x1, x2 (not marked here), since the control interface 66 lies on a different potential accordingly.

The arrangement of the control interface 66 is independent of the inlays 55.

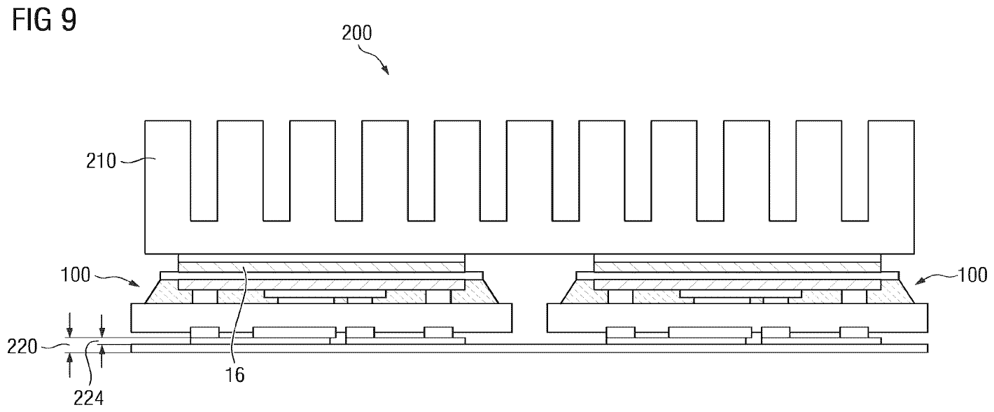

FIG. 9 schematically shows a power electronics assembly 200 having two power modules 100, a heat sink 210 and an assembly substrate 220 with a metallization 224. The assembly substrate 220 in this case can be manufactured from known materials for PCB technology, since the power-intensive components are transferred onto the power modules 100. As a consequence, assemblies 200 can be designed in a very flexible manner for the widest range of applications and can also be cooled for high-power applications.

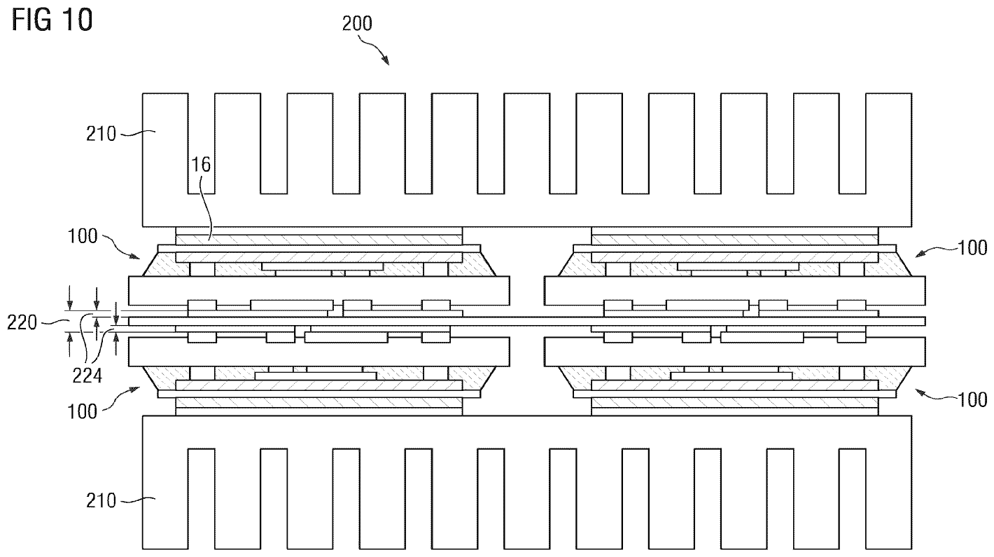

FIG. 10 schematically shows a power electronics assembly 200 as per FIG. 9, the assembly substrate 220 being loaded and contacted on both sides with two power modules 100 in each case. It is thereby possible to achieve a very high power density, since the attachment of the power modules 100 to the assembly substrate 220, for example via a metallization 224 on both sides, can still be realized with low inductance while the dissipation of heat is realized effectively at the same time by means of the heat sinks arranged on both sides. It applies generally that the power electronics assembly 200 and the assembly substrate 220 are designed in such a way that the contact elements 62,64 of the power modules 100 each have joining partners on the assembly substrate 220. These can be corresponding sockets or counterparts for the relevant contact elements 62,64.

In summary, the present disclosure describes loadable power modules comprising a power substrate with a metallization, at least one switchable die with power interfaces, an interposer, and at least a first and a second contact element. The contact elements each provide an electrical contacting for one of the power interfaces of the die at the interposer. In order to specify a power module which can be loaded in a conventional production line, and which allows low-inductance attachment to an assembly without clean-room conditions, for example in an SMD assembly line, the die is joined to the first metallization of the power substrate and to the interposer and is arranged between the power substrate and the interposer, that a gap which is formed by the first substrate, the interposer, and the die is closed off by an insulation material so that the die is surrounded by the insulation material, the power substrate, and the interposer, and that the interposer is embodied in such a way that one or more of the contact elements project through the interposer and/or the interposer provides one or more of the contact elements.

### REFERENCE SIGNS

100 Loadable power module
10 Power substrate
12 Core
14 First metallization of the power substrate
16 Second metallization of the power substrate and thermal interface
18 Recontacting
20 Insulation material
22 Gap
40 Switchable die
42 First power interface of the die
44 Second power interface of the die
46 Control interface of the die
50 Interposer
55 Metallic inlay
56 Via
62 First contact element
64 Second contact element
66 Control interface of the interposer
200 Power electronics assembly
210 Heat sink
220 Assembly substrate
224 Metallization of the assembly substrate

What is claimed is:

1. A power electronics assembly having an assembly substrate in electrical contact with two loadable power modules, wherein the two loadable power modules each comprise:
a power substrate with a first metallization;
a switchable die with power interfaces;
an interposer; and
a first contact element and a second contact element, each of which provides an electrical contact for one of the power interfaces at the interposer;
wherein the die is joined to the metallization of the power substrate and to the interposer, and
is arranged between the power substrate and the interposer;
wherein a gap is defined between the first substrate, the interposer, and the die, and the gap is closed off by an insulation material so the die is surrounded by the insulation material, the power substrate, and the interposer;
wherein at least one of the first contact element and the second contact element projects through the interposer and/or is part of the interposer.

2. The power electronics assembly as claimed in claim 1, wherein the interposers are oriented toward the assembly substrate.

3. The power electronics assembly as claimed in claim 1, wherein the power modules are arranged between the assembly substrate and a heat sink.

4. The power electronics assembly as claimed in claim 1, wherein the interposer comprises a multilayer circuit support.

5. The power electronics assembly as claimed in claim 1, wherein:
the interposer includes an opening for at least one of the contact elements; and
the opening is in electrical contact with the first metallization.

6. The power electronics assembly as claimed in claim 1, wherein the power interfaces and control interfaces of all dies are on a shared side of the interposer, the shared side opposite to the power substrate.

7. The power electronics assembly as claimed in claim 1, wherein at least one of the contact elements provides contact by a compression method.

8. The power electronics assembly as claimed in claim 1, wherein at least one of the contact elements provides contact by a joining method.

9. The power electronics assembly as claimed in claim 1, wherein at least one of the contact elements provides contact by a spring force.

10. The power electronics assembly as claimed in claim 1, wherein the interposer includes a first metallic inlay in electrical contact with a first power interface of the die and the first contact element.

11. The power electronics assembly as claimed in claim 10, wherein the interposer includes a second metallic inlay in electrical contact with a second power interface of the die and with the second contact element.

12. The power electronics assembly as claimed in claim 1, wherein a leakage distance in the gap between a recontacting of the electrical contact for the first power interface and the second power interface is smaller than a clearance between the first contact element and the second contact element projecting from the interposer.

13. The power electronics assembly as claimed in claim 1, wherein:
the interposer includes a control interface in electrical contact with a control interface of the die; and
the control interface of the interposer is arranged between the first and the second contact element.

14. A converter comprising:
a power electronics assembly as claimed in claim 1, to convert DC voltage into AC voltage and/or vice versa.

15. An electric vehicle comprising:
a wheel; and
an electric drive providing power to the wheel, the electric drive including a converter as claimed in claim 14 as part of an electric drive.
